(19) United States
(12) Patent Application Publication
(10) Pub. No.: US 2025/0321459 A1
(43) Pub. Date: Oct. 16, 2025

(54) DISPLAY STACKING AND SPLICING STRUCTURE

(71) Applicant: E Ink Holdings Inc., HSINCHU (TW)

(72) Inventors: Yen-Ze HUANG, HSINCHU (TW); Jen-Shiun HUANG, HSINCHU (TW); Hsin-Tao HUANG, HSINCHU (TW)

(21) Appl. No.: 19/173,827

(22) Filed: Apr. 9, 2025

Related U.S. Application Data
(60) Provisional application No. 63/634,430, filed on Apr. 15, 2024.

(30) Foreign Application Priority Data
Aug. 28, 2024 (TW) 113132452

(51) Int. Cl. G02F 1/1679; G02F 1/167; G02F 1/16755; G06F 3/14; H05K 1/18

(52) U.S. Cl. CPC G02F 1/1679; G02F 1/167; G02F 1/16755; G06F 3/1446; H05K 1/189; H05K 2201/10128

(57) ABSTRACT

A display stacking and splicing structure includes plural display panels, plural dummy substrates, at least one optical clear resin (OCR) layer, and a support plate. Each of the display panels has a display area and a border area surrounding the display area. The left side of the border area of one of the display panels overlaps the right side of the border area of another one of the display panels in a vertical direction, thereby forming plural spaces. The dummy substrates are disposed in the spaces. The OCR layer is disposed between one of the display panels and one of the dummy substrates. The support plate is disposed below the display panels.

### CROSS-REFERENCE TO RELATED APPLICATION

This application claims priority to U.S. Provisional Application Ser. No. 63/634,430 filed Apr. 15, 2024, and Taiwan Application Serial Number 113132452, filed Aug. 28, 2024, the disclosures of which are incorporated herein by reference in their entireties.

### BACKGROUND

### Field of Invention

The present disclosure relates to a display device, and more particularly, to a display stacking and splicing structure.

### Description of Related Art

Reflective display devices (for example, electronic paper) are widely used as display monitors in today's market for various consumer electronic products. Display dielectric layers of the reflective devices consist of microcapsules having white particles and black particles. By applying a voltage to the display dielectric layers, the white particles and black particles are driven to move, such that every pixel displays black, white or grayscale. Because the reflective display devices illuminate the display dielectric layers by incident light to achieve display, a backlight is not required and a reduction of power consumption is realized.

In terms of commercial requirements, there are a lot of large-sized display applications, such as displays at exhibition halls, which must be realized by splicing multiple displays. For example, when electronic paper display devices are used for splicing displays, the displays are usually spliced directly in a tiled configuration (i.e., spliced adjacently along a horizontal direction) such that the display devices are placed two by two adjacent to each other. As a result, the display areas after splicing will have border areas of twice the width, resulting in an excessively large splicing slit, affecting the visual experience, and adversely affecting product competitiveness.

### SUMMARY

According to embodiments of the present disclosure, a display stacking and splicing structure comprises plural display panels, plural dummy substrates, at least one optical clear resin layer and a support plate. Each of the display panels has a display area and a border area surrounding the display area. A first side of the border area of one of the display panels and a second side of the border area of another one of the display panels overlap in a vertical direction, thereby forming a plurality of spaces. The dummy substrates are disposed in the spaces respectively. The optical clear resin layer is disposed between one of the display panels and one of the dummy substrates. The support plate is disposed below the display panels. At least one of the dummy substrates extends from above the display area of one of the display panels to above the display area of another of the display panels.

In some embodiments, the display stacking and splicing structure further comprises an adhesive layer. The adhesive layer is disposed between at least one of the dummy substrates and the support plate, and between at least one of the display panels and the support plate.

In some embodiments, the display stacking and splicing structure further comprises a translucent cover and another optical clear resin layer. The translucent cover is disposed above the display panels and the dummy substrates. Another optical clear resin layer is disposed between at least one of the dummy substrates and the translucent cover, and between at least one of the display panels and the translucent cover.

In some embodiments, the support plate and the translucent cover are glass sheets.

In some embodiments, one of the dummy substrates and at least one of the display panels overlap in the vertical direction.

In some embodiments, at least one of the dummy substrates extends from below the display area of one of the display panels to below another of dummy substrates.

In some embodiments, each of the display panels has a flexible printed circuit board, the support plate has a plurality of trenches, and the flexible printed circuit boards pass through the trenches of the support plate respectively.

In some embodiments, the support plate is metal element or bakelite element.

In some embodiments, the support plate has a plurality of protrusions, and each of the protrusions extends into one of the spaces.

In some embodiments, the protrusions of the support plate define a ladder structure.

In some embodiments, the optical clear resin layer extends from below one of the display panels to below another of the display panels.

In some embodiments, the optical clear resin layer extends from above one of the display panels to above another of the display panels.

In some embodiments, the optical clear resin layer extends from below one of the dummy substrates to below another of the dummy substrates.

In some embodiments, the optical clear resin layer extends from above one of the dummy substrates to above another of the dummy substrates.

In some embodiments, the display panels are electronic paper display panels.

In some embodiments, a refractive index of the dummy substrates is the same as a refractive index of the optical clear resin layer.

In embodiments of the present disclosure, since the display stacking and splicing structure overlaps different sides (such as the left side and the right side) of two border areas of two upper and lower display panels in a vertical direction, the display stacking and splicing structure forms spaces, and use the dummy substrates and the optical clear resin layers to fill the spaces to achieve the effect of support and flattening. Therefore, the width of the splicing slit will be reduced from border areas of twice the width in the traditional tiled configuration to the single-width border area, thereby enhancing the visual experience and increasing product competitiveness.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a display stacking and splicing structure according to one embodiment of the present disclosure.

FIG. 2 is a cross-sectional view of a display stacking and splicing structure according to another embodiment of the present disclosure.

FIG. 3 is a top view of a support plate of FIG. 2.

FIG. 4 is a cross-sectional view of a display stacking and splicing structure according to another embodiment of the present disclosure.

FIG. 5 is a top view of a support plate of FIG. 4.

FIG. 6 is a cross-sectional view of a display stacking and splicing structure according to another embodiment of the present disclosure.

FIG. 7 is a top view of a support plate of FIG. 6.

FIG. 8 is a cross-sectional view of a display stacking and splicing structure according to one embodiment of the present disclosure.

FIG. 9 is a top view of a support plate of FIG. 8.

FIG. 10 is a cross-sectional view of a display stacking and splicing structure according to another embodiment of the present disclosure.

FIG. 11 is a top view of a support plate if FIG. 10.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

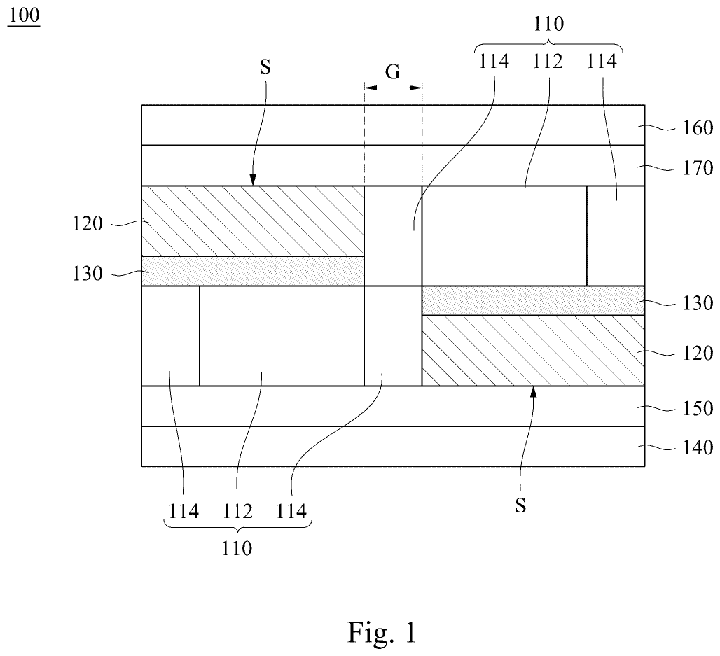

FIG. 1 is a cross-sectional view of a display stacking and splicing structure 100 according to one embodiment of the present disclosure. As shown in the figure, the display and splicing structure 100 includes plural display panels 110, plural dummy substrates 120, at least one optical clear resin layer 130 and a support plate 140. Each of the display panels 110 has a display area 112 and border areas 114 surrounding the display area 112. The left side of the border area 114 of the display panel 110 overlaps the right side of the border area 114 of another display panel 110 in a vertical direction to form plural spaces S. For example, two step differences are formed above the lower left display panel 110 of FIG. 1 and below the upper right display panel 110 of FIG. 1, respectively. The dummy substrates 120 fill in the spaces S, respectively. With such a configuration, the dummy substrates 120 and the display panels 110 may overlap in the vertical direction. In addition, the optical clear resin layer 130 is disposed between the display panel 110 and the corresponding dummy substrate 120 to bond the display panel 110 and the dummy substrate 120. The support plate 140 is disposed below the display panels 110 and the dummy substrates 120.

In some embodiments, the display stacking and splicing structure 100 further includes an adhesive layer 150, a translucent cover 160 and another optical clear resin layer 170. The adhesive layer 150 is disposed between the dummy substrates 120 and the support plate 140, and between the display panels 110 and the support plate 140. The translucent cover 160 is disposed above the display panels 110 and the dummy substrates 120. The optical clear resin layer 170 is disposed between the dummy substrates 120 and the translucent cover 160, and between the display panels 110 and the translucent cover 160. In addition, orthogonal projections of the overlapping border areas 114 on the translucent cover 160 in the vertical direction may define a splicing slit G of the display stacking and splicing structure 100.

In this embodiment, the display panels 110 are stacked in two layers, the number of the display panels 110, the dummy substrates 120 and the optical clear resin layers 130 are two, but the present disclosure is not limited thereto. The display panels 110 can be electronic paper display panels. The translucent cover 160 and the support plate 140 can be glass sheets. The dummy substrates 120 can be glass sheets or polymethyl methacrylate (PMMA) films. The optical clear resin layers 130 and the optical clear resin layer 170 can be acrylic optical clear resin. A refractive index of the dummy substrates 120 and a refractive index of the optical clear resin layer 130 can be the same (such as 1.48), which is advantageous for passage of light and decreasing interface reflection.

Specifically, since the display stacking and splicing structure 100 overlaps different sides (such as the left side and the right side) of the two border areas 114 of the two upper and lower display panels 110 in the vertical direction, the display stacking and splicing structure 100 forms the spaces S, and uses the dummy substrates 120 and the optical clear resin layers 130 to fill the spaces S to achieve the effect of supporting and flattening. Therefore, the width of the splicing slit G will be reduced from the border areas of twice the width in the traditional tiled configuration to the single-width border area 114, thereby enhancing the visual experience and increasing product competitiveness.

It should be understood that the connection relationships of components, materials and effects that have been described will not be repeated. In the following description, other types of display stacking and splicing structures will be described.

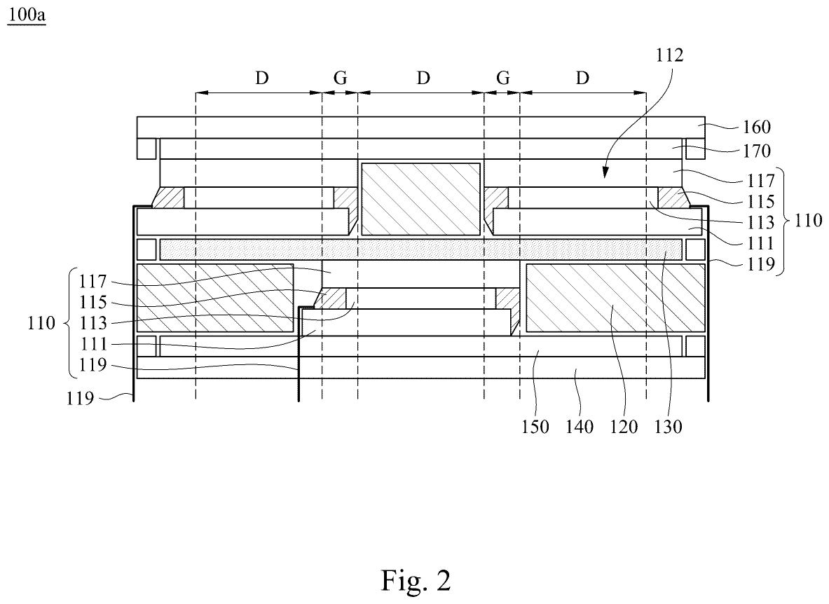

FIG. 2 is a cross-sectional view of a display stacking and splicing structure 100a according to another embodiment of the present disclosure. The display stacking and splicing structure 100a includes display panels 110, dummy substrates 120, an optical clear resin layer 130, a support plate 140, an adhesive layer 150, a translucent cover 160 and an optical clear resin layer 170. Each of the display panels 110 may include a lower substrate 111, an electronic ink layer 113, sealing glue 115, a front panel 117 and a flexible printed circuit board 119. Orthogonal projections of vertically overlapping display areas 112 on the translucent cover 160 may define display areas D of the display stacking and splicing structure 100a. This embodiment differs from the embodiment of FIG. 1 in that the number of the display panels 110 and the dummy substrates 120 is three, number of the optical clear resin layer 130 is one, and the optical clear resin layer 130 extends from below one of the display panels 110 (such as the upper left display panel 110) to below another of the display panel 110 (such as the upper right display panel 110). In addition, the optical clear resin layer 130 extends from above one of the dummy substrates 120 (such as the lower left dummy substrate 120) to above another of the dummy substrates 120 (such as the lower right dummy substrate 120).

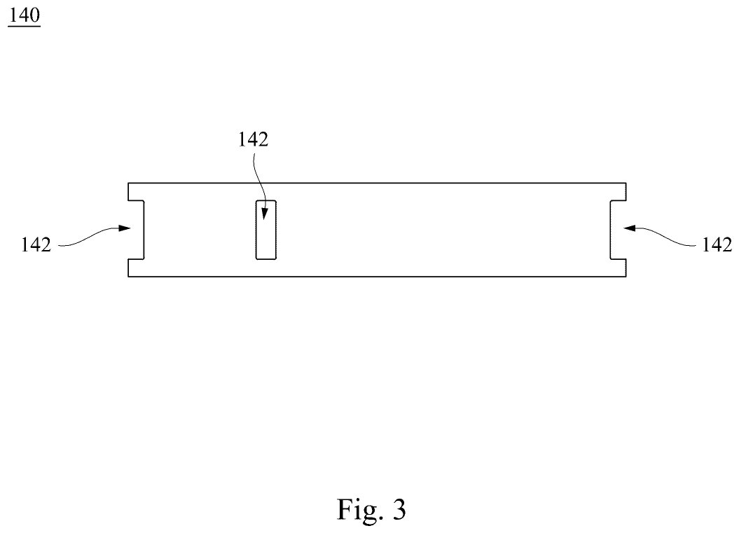

FIG. 3 is a top view of the support plate 140 of FIG. 2. As shown in FIG. 2 and FIG. 3, the support plate 140 of the display stacking and splicing structure 100a has plural trenches 142, the flexible printed circuit boards 119 extend from the lower substrates 111 of the display panels 110 to the support plate 140, and the flexible printed circuit boards 119 respectively pass through the trenches 142 of the support plate 140, such that the flexible printed circuit boards 119 may connect to other electronic devices from outside of the support plate 140. In this embodiment, the number of the trenches 142 and the flexible printed circuit boards 119 is three, and the number of the trenches 142 of the support plate 140 is the same as the number of the display panels 110, but the present disclosure is not limited thereto. In another embodiment of the present disclosure, the number of the trenches 142 of the support plate 140 is lower than the number of the display panels 110, that is, multiple flexible printed circuit boards 119 can share a trench 142.

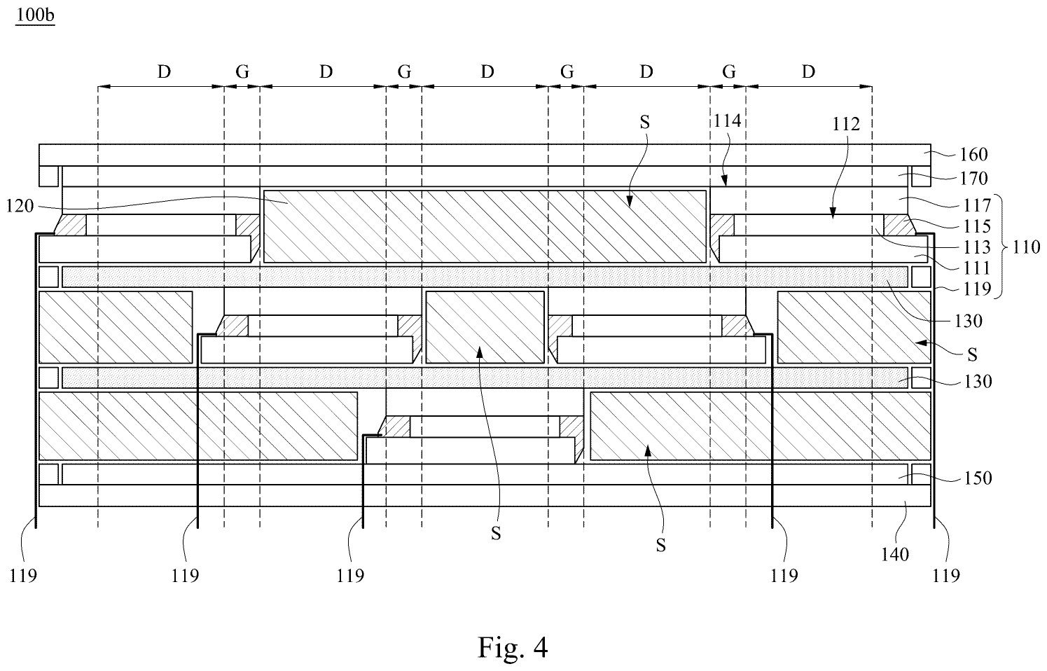

FIG. 4 is a cross-sectional view of a display stacking and splicing structure 100b according to another embodiment of the present disclosure. The display stacking and splicing structure 100b includes display panels 110, dummy substrates 120, optical clear resin layers 130, a support plate 140, an adhesive layer 150, a translucent cover 160 and an optical clear resin layer 170. The difference between this embodiment and the embodiment of FIG. 2 is that the number of the display panels 110 is five, the display stacking and splicing structure 100b is stacked in three layers, the number of the dummy substrates 120 is six, the number of the optical clear resin layers 130 is two, one of the dummy substrates 120 (such as dummy substrate 120 in the upper layer) extends from above the display area 112 of one of the display panels 110 (such as the display panel 110 on the left side of the middle layer) to above the display area 112 of another one of the display panels 110 (such as display panel 110 on the right side of the middle layer), at least one of the dummy substrates 120 (such as the dummy substrate 120 on the left side of the lower layer) extends from below the display area 112 of one of the display panels 110 (such as the display panel 110 on the left side of the middle layer) to below another of the dummy substrates 120 (such as the dummy substrate 120 on the left side of the middle layer), and the lower optical clear resin layer 130 extends from below one of the dummy substrates 120 (such as the dummy substrate 120 on the left side of the middle layer) to below another of the dummy substrates 120 (such as the dummy substrate 120 on the right side of the middle layer).

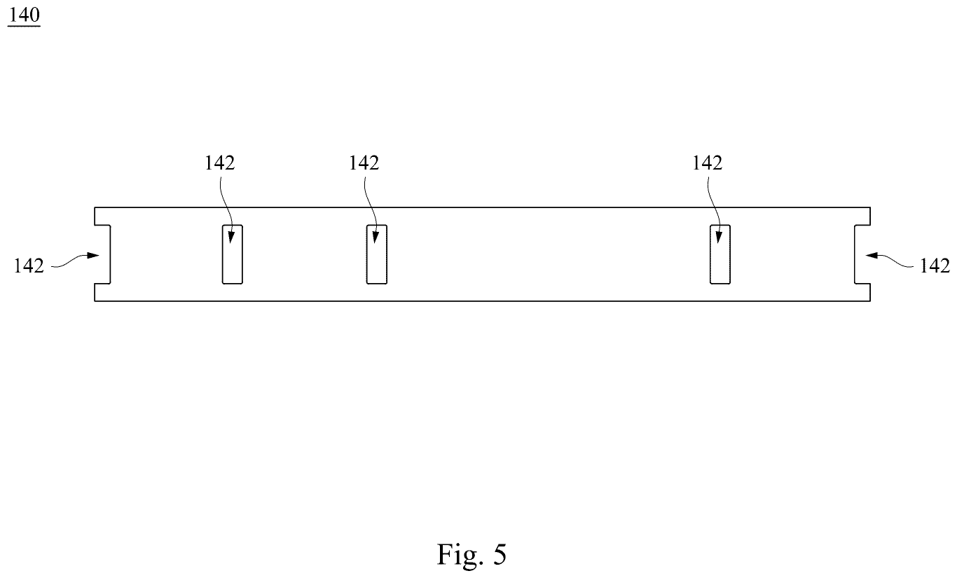

FIG. 5 is a top view of the support plate 140 of FIG. 4. As shown in FIG. 4 and FIG. 5, the flexible printed circuit boards 119 of the display stacking and splicing structure 100b extend from lower substrates 111 of the display panels 110 to the support plate 140, and the flexible printed circuit boards 119 pass through the trenches 142 of the support plate 140 respectively. In this embodiment, the number of the trenches 142 and the flexible printed circuit boards 119 is both five.

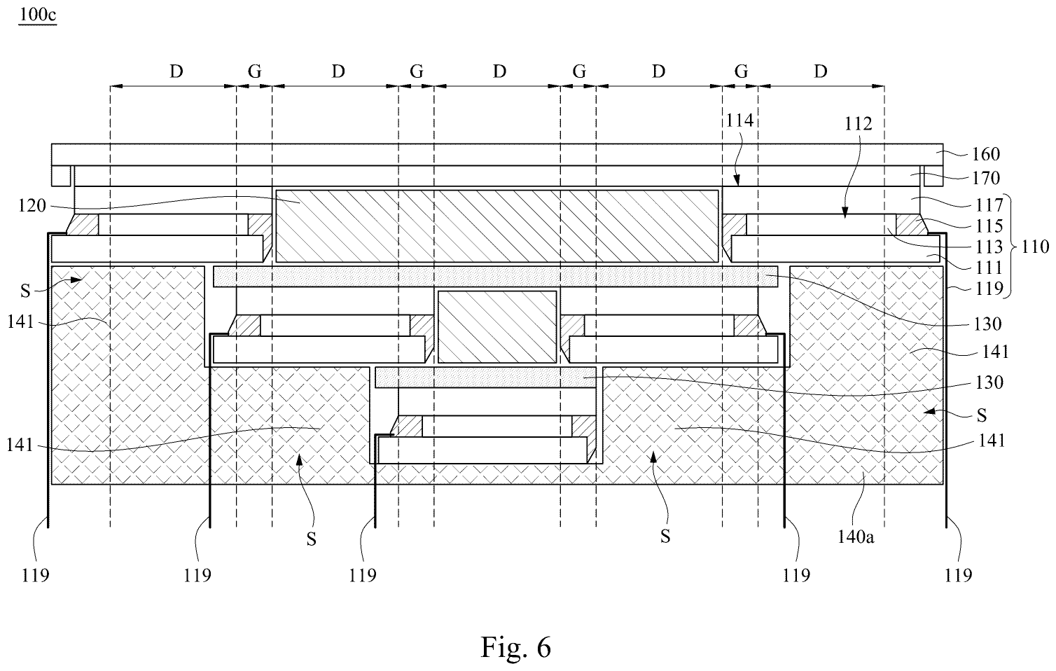

FIG. 6 is a cross-sectional view of a display stacking and splicing structure 100c according to another embodiment of the present disclosure. The display stacking and splicing structure 100c includes display panels 110, dummy substrates 120, optical clear resin layers 130, a support plate 140a, a translucent cover 160 and an optical clear resin layer 170. The difference between this embodiment and the embodiment of FIG. 4 is that the number of the dummy substrates 120 is two, the support plate 140a has plural protrusions 141 and the upper optical clear resin layer 130 extends from above one of the display panels 110 (such as the display panel 110 on the left side of the middle layer) to above another of the display panels 110 (such as the display panel 110 on the right side of the middle layer). The protrusions 141 of the support plate 140a can define a ladder structure. In this embodiment, the support plate 140a can be metal element or bakelite element.

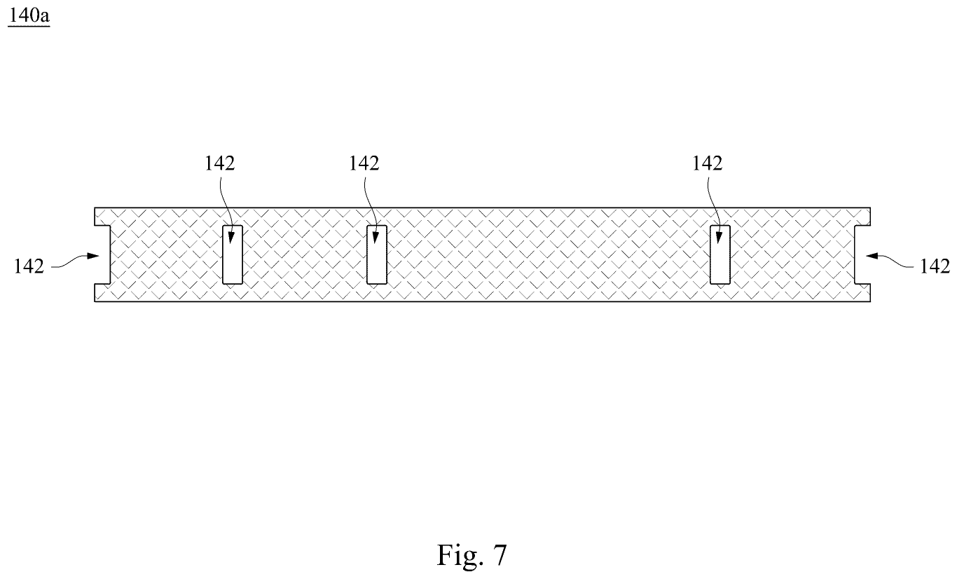

FIG. 7 is a top view of the support plate of FIG. 6. As shown in FIG. 6 and FIG. 7, the flexible printed circuit boards 119 of the display stacking and splicing structure 100c extend from lower substrates 111 of the display panels 110 to the support plate 140a, and the flexible printed circuit boards 119 respectively pass through the trenches 142 of the support plate 140a. In this embodiment, the number of the trenches 142 and the flexible printed circuit boards 119 is both five.

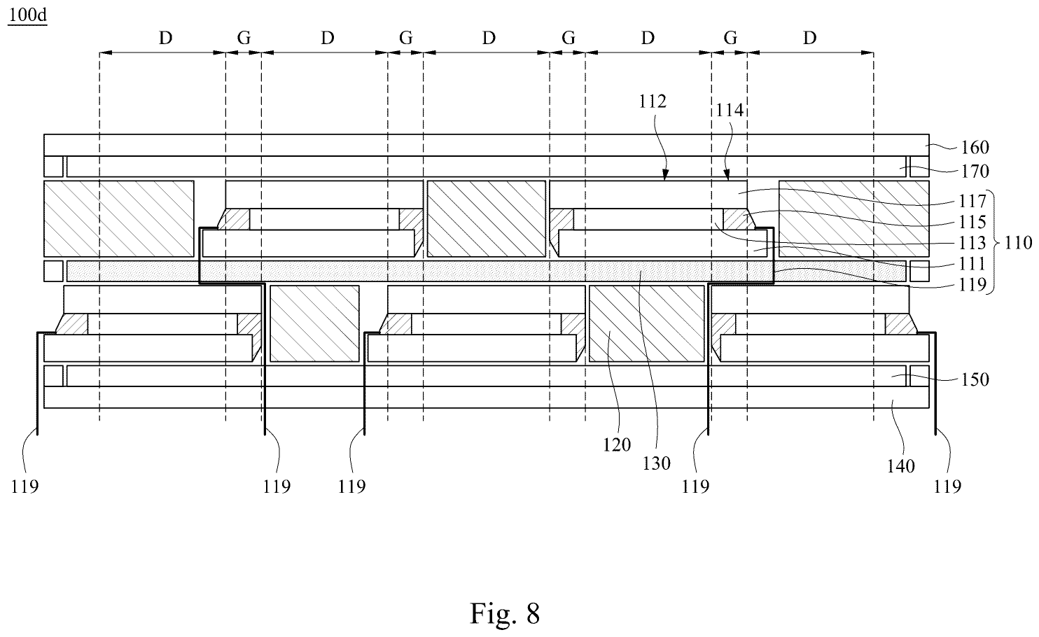

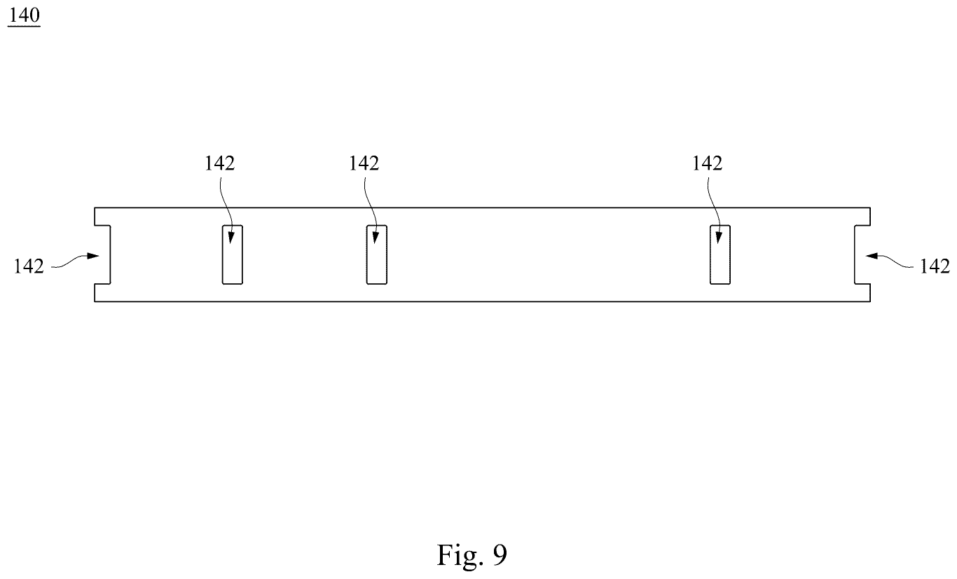

FIG. 8 is a cross-sectional view of a display stacking and splicing structure 100d according to one embodiment of the present disclosure. FIG. 9 is a top view of the support plate 140 of FIG. 8. As shown in FIG. 8 and FIG. 9, the display stacking and splicing structure 100d includes display panels 110, dummy substrates 120, an optical clear resin layer 130, a support plate 140, an adhesive layer 150, a translucent cover 160 and an optical clear resin layer 170. The difference between this embodiment and the embodiment of FIG. 2 is that the number of the display panels 110 and the dummy substrates 120 is five, and the number of the flexible printed circuit boards 119 and the trenches 142 of the support plate 140 is five. In addition, the optical clear resin layer 170 extends from above the dummy substrate 120 on the left side of the upper layer to above the dummy substrate 120 on the right side of the upper layer, the optical clear resin layer 130 extends from above the dummy substrate 120 on the left side of the lower layer to above the dummy substrate 120 on the right side of the lower layer, and the adhesive layer 150 extends from below the display panel 110 on the left side of the upper layer to above the display panel 110 on the right side of the upper layer.

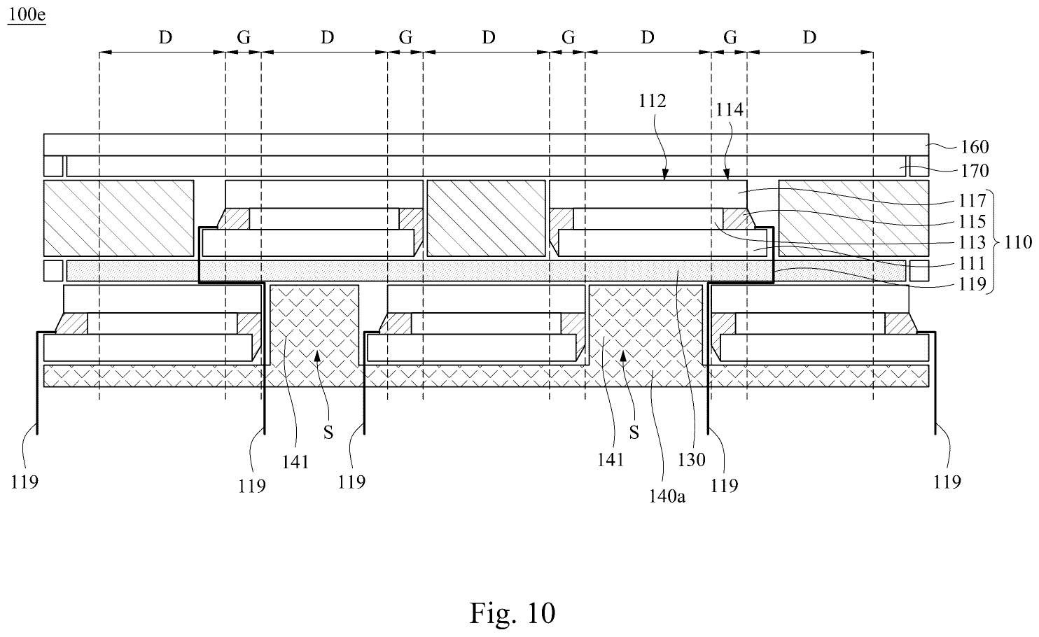

FIG. 10 is a cross-sectional view of a display stacking and splicing structure 100e according to another embodiment of the present disclosure. The display stacking and splicing structure 100e includes display panels 110, dummy substrates 120, an optical clear resin layer 130, a support plate 140a, a translucent cover 160 and an optical clear resin layer 170. The difference between this embodiment and the embodiment of FIG. 8 is that the number of the dummy substrates 120 is three, and the support plate 140a has plural protrusions 141. The protrusions 141 of the support plate 140a can define a ladder structure. In this embodiment, the support plate 140a can be metal element or bakelite element.

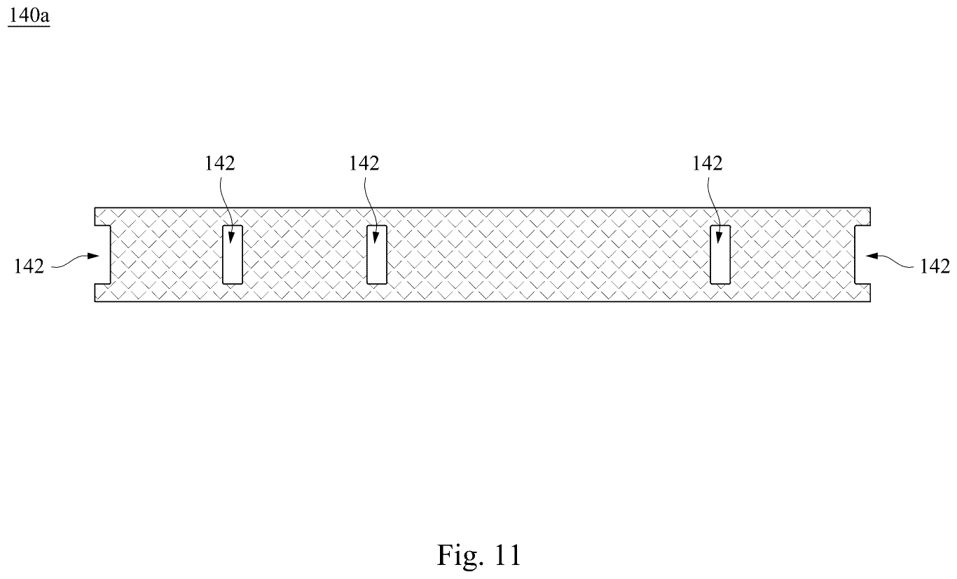

FIG. 11 is a top view of the support plate 140a of FIG. 10. As shown FIG. 10 and FIG. 11, the flexible printed circuit boards 119 of the display stacking and splicing structure 100e extend from lower substrates 111 of the display panels 110 to the support plate 140a, and the flexible printed circuit boards 119 respectively pass through the trenches 142 of the support plate 140a. In this embodiment, the number of the trenches 142 and the flexible printed circuit boards 119 is five.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A display stacking and splicing structure, comprising:
a plurality of display panels, wherein each of the display panels has a display area and a border area surrounding the display area, a first side of the border area of one of the display panels and a second side of the border area of another one of the display panels overlap in a vertical direction, thereby forming a plurality of spaces;
a plurality of dummy substrates disposed in the spaces respectively;
at least one optical clear resin layer, wherein the optical clear resin layer is disposed between one of the display panels and one of the dummy substrates; and
a support plate disposed below the display panels;
wherein at least one of the dummy substrates extends from above the display area of one of the display panels to above the display area of another of the display panels.

2. The display stacking and splicing structure of claim 1, further comprising:
an adhesive layer disposed between at least one of the dummy substrates and the support plate, and between at least one of the display panels and the support plate.

3. The display stacking and splicing structure of claim 1, further comprising:
a translucent cover disposed above the display panels and the dummy substrates; and
another optical clear resin layer disposed between at least one of the dummy substrates and the translucent cover, and between at least one of the display panels and the translucent cover.

4. The display stacking and splicing structure of claim 1, wherein the support plate and the translucent cover are glass sheets.

5. The display stacking and splicing structure of claim 1, wherein one of the dummy substrates and at least one of the display panels overlap in the vertical direction.

6. The display stacking and splicing structure of claim 1, wherein at least one of the dummy substrates extends from below the display area of one of the display panels to below another of dummy substrates.

7. The display stacking and splicing structure of claim 1, wherein each of the display panels has a flexible printed circuit board, the support plate has a plurality of trenches, and the flexible printed circuit boards pass through the trenches of the support plate respectively.

8. The display stacking and splicing structure of claim 1, wherein the support plate is metal element or bakelite element.

9. The display stacking and splicing structure of claim 6, wherein the support plate has a plurality of protrusions, and each of the protrusions extends into one of the spaces.

10. The display stacking and splicing structure of claim 9, wherein the protrusions of the support plate define a ladder structure.

11. The display stacking and splicing structure of claim 1, wherein the optical clear resin layer extends from below one of the display panels to below another of the display panels.

12. The display stacking and splicing structure of claim 1, wherein the optical clear resin layer extends from above one of the display panels to above another of the display panels.

13. The display stacking and splicing structure of claim 1, wherein the optical clear resin layer extends from below one of the dummy substrates to below another of the dummy substrates.

14. The display stacking and splicing structure of claim 1, wherein the optical clear resin layer extends from above one of the dummy substrates to above another of the dummy substrates.

15. The display stacking and splicing structure of claim 1, the display panels are electronic paper display panels.

16. The display stacking and splicing structure of claim 1, wherein a refractive index of the dummy substrates is the same as a refractive index of the optical clear resin layer.

17. A display stacking and splicing structure, comprising:
a plurality of display panels, wherein each of the display panels has a display area and a border area surrounding the display area, a first side of the border area of one of the display panels and a second side of the border area of another one of the display panels overlap in a vertical direction, thereby forming a plurality of spaces;
a plurality of dummy substrates disposed in the spaces respectively;
at least one optical clear resin layer, wherein the optical clear resin layer is disposed between one of the display panels and one of the dummy substrates; and
an adhesive layer disposed below at least one of the dummy substrates and at least one of the display panels.

18. The display stacking and splicing structure of claim 17, wherein one of the dummy substrates and at least one of the display panels overlap in the vertical direction.

19. The display stacking and splicing structure of claim 17, wherein a refractive index of the dummy substrates is the same as a refractive index of the optical clear resin layer.
